(19) United States
(12) Patent Application Publication
(10) Pub. No.: US 2006/0228492 A1
(43) Pub. Date: Oct. 12, 2006

(54) Method for manufacturing SIMOX wafer

(75) Inventors: Yoshiro Aoki, Tokyo (JP); Mitsuru Sudo, Tokyo (JP); Tetsuya Nakai, Tokyo (JP)

Correspondence Address: PILLSBURY WINTHROP SHAW PITTMAN, LLP, P.O. BOX 10500, MCLEAN, VA, 22102, US

(73) Assignee: SUMCO CORPORATION, Tokyo (JP)

(21) Appl. No.: 11/100,610

(22) Filed: Apr. 7, 2005

(51) Int. Cl. C23C 14/00; B05D 3/02

(52) U.S. Cl. 427/523; 427/372.2

(57) ABSTRACT

In the method for manufacturing a SIMOX wafer, oxygen ions are implanted into a silicon wafer, then the silicon wafer is subjected to a prescribed heat treatment so as to form a buried oxide layer in the silicon wafer. The prescribed heat treatment includes: a step of ramping up a temperature of the silicon wafer in a low oxygen partial pressure gas atmosphere having an oxygen partial pressure ratio of less than 5%; either or both of a step of oxidizing the silicon wafer in a high oxygen partial pressure gas atmosphere having an oxygen partial pressure ratio of 5% or more and a step of annealing the silicon wafer in a low oxygen partial pressure gas atmosphere having an oxygen partial pressure ratio of less than 5%; and a step of ramping down the temperature of the silicon wafer in a low oxygen partial pressure gas atmosphere having an oxygen partial pressure ratio of less than 5%. A hydrogen chloride gas is mixed with the low oxygen partial pressure gas having an oxygen partial pressure ratio of less than 5% in at least one step from among the ramp-up step, the anneal step and the ramp-down step.

### BACKGROUND OF THE INVENTION

1. Field of the Invention

The present invention relates to a method for manufacturing a SIMOX (Separation by IMplanted OXygen) wafer. More specifically, the invention relates to a method for manufacturing a SIMOX wafer having reduced metal contamination in a surface and having a buried oxide layer with an excellent dielectric withstanding voltage.

2. Background Art

The SIMOX process (see Reference Document 1, for example) is familiar as one type of a method for manufacturing a silicon-on-insulator (SOI) wafer. In the SIMOX process, oxygen ions are implanted at an acceleration energy of about 200 keV and a dose of about 2×10¹⁸ atoms/cm² to form an as-implanted (referring to the state following oxygen ion implantation and before heat treatment) stoichiometric buried oxide (BOX) layer, after which heat treatment is performed to regenerate a crystallinity of the SOI layer and modify the BOX layer. SIMOX wafers manufactured by this process are referred to as “high-dose SIMOX wafers.”

However, a number of problems are associated with such high-dose SIMOX wafers, including the generation of numerous threading dislocations and a long time needed for oxygen ion implantation, which raises production costs.

Many investigations have been carried out to reduce the threading dislocations in the SOI layer and to lower production costs, resulting in the development of a low-dose SIMOX technique (see, for example, Reference Document 2). In this low-dose SIMOX technique, by implanting oxygen ions at an acceleration energy of 180 keV and a dose of 4×10¹⁷ atoms/cm² then carrying out heat treatment, a continuous BOX layer can be formed. Formation of this continuous BOX layer is possible only at the acceleration energy of 180 keV and the dose of about 4×10¹⁷ atoms/cm², and so this dose is called the “dose window.”

However, the BOX layer in the above low-dose SIMOX wafer has a small thickness, resulting in a decline in the reliability of the BOX layer.

The ITOX (Internal Thermal Oxidation) technique was developed to solve this problem (e.g., see Reference Documents 3 and 4). The ITOX technique is a process for increasing the thickness of the BOX layer by carrying out annealing for realizing a theoretical BOX film thickness (calculated from the oxygen ion dose) in an argon atmosphere containing an oxygen concentration of 1% or less, then carrying out oxidation treatment in an argon atmosphere containing an oxygen concentration of more than 1%. The introduction of this ITOX technique has increased a reliability of the BOX layers in the low-dose SIMOX wafer.

Yet, even with a low-dose SIMOX process that incorporates this ITOX technique, because the oxygen ion dose remains high at 4×10¹⁷ atoms/cm², ion implantation takes several hours per batch, in addition to which ITOX treatment must also be carried out. As a result, heat treatment time is also long, lowering the production efficiency and increasing production costs.

A method for manufacturing a SIMOX wafer which divides oxygen ion implantation into two separate steps has been disclosed (see Reference Document 5, for example). In this two-step oxygen ion implantation process, a first oxygen ion implantation is carried out with the silicon wafer heated to 200 to 700° C., after which the silicon wafer is cooled to 25 to 200° C., in which state a second oxygen ion implantation is carried out. In this two-step oxygen ion implantation process, heating the silicon wafer at the time of the first oxygen ion implantation serves to maintain the silicon wafer surface as single-crystal silicon, and the second oxygen ion implantation forms an amorphous layer in the silicon wafer. By then subjecting this silicon wafer to oxidation treatment at a high temperature, an SOI structure is formed in the silicon wafer. In this heat treatment, a high-density defect layer having polysilicon, twinning, and stacked faults are formed from the amorphous layer. Because of a rapid diffusion of oxygen in a region where this high-density defect layer has formed, a BOX layer having up to about twice the thickness theoretically anticipated from the oxygen ion dose can be formed. SIMOX wafers manufactured by this process are referred to as MLD-SIMOX, which stands for “modified low dose SIMOX.”

However, in each of the foregoing prior-art SIMOX processes, forming a high-quality BOX layer by these SIMOX processes requires that the wafer be held at an elevated temperature of 1300° C. or more during heat treatment. At the time of the heat treatment, the wafer incurs metal contamination, as a result of which the surface of the wafer is readily subject to the deposition of metal impurities. One method for removing these metal impurities from the wafer surface that has seen practical application in device fabrication involves the mixture of a hydrogen chloride gas with the oxygen-containing atmosphere. This method is generally called “hydrochloric acid oxidation.”

Unfortunately, we have found that, although the mixture of a fixed amount of hydrogen chloride gas with the oxygen-containing inert gas atmosphere during the heat treatment in the method for manufacturing a MLD-SIMOX wafer is able to reduce the metal contamination in the surface of the wafer, the dielectric withstanding voltage of the BOX layer decreases.

Reference Document 1: K. Izumi, et al.: “CMOS device fabricated on buried SiO₂ layers formed by oxygen implantation into silicon,” Electronics Letters 14, 593-594 (1978).

Reference Document 2: S. Nakajima, et al.: “Analysis of buried oxide layer formation and mechanism of threading dislocation generation in the sub-stoichiometric oxygen dose region,” Journal of Materials Research 8, 523-534 (1993).

Reference Document 3: S. Nakajima, et al.: Thickness increment of buried oxide in a SIMOX wafer by high-temperature oxidation,” Proceedings, 1994 IEEE International SOI Conference, 71-72 (1994).

Reference Document 4: Japanese Unexamined Patent Application, First Publication No. H07-263538.

Reference Example 5: U.S. Pat. No. 5,930,643.

### SUMMARY OF THE INVENTION

It is thus an object of the present invention to provide a method for manufacturing a SIMOX wafer which is capable of reducing metal contamination in a surface of a wafer and can also enhance an dielectric withstanding voltage of a BOX layer.

To achieve this object, we have conducted extensive investigations on methods for admixing hydrogen chloride gas in an oxygen-containing inert gas atmosphere. As a result, we have discovered that, among heat treatment steps carried out on an oxygen ion-implanted silicon wafer, when a hydrogen chloride gas is admixed in a heat treatment step carried out in a high oxygen partial pressure atmosphere containing a large amount of oxygen, the oxide film in the surface of the wafer becomes thicker, which suppresses an increase in a thickness of a BOX layer and thus lowers a dielectric withstanding voltage of the BOX layer. However, when the hydrogen chloride gas is admixed during heat treatment in a low oxygen partial pressure atmosphere containing a small amount of oxygen, no decline occurs in the dielectric withstanding voltage of the BOX layer. In particular, we have found that metal contamination in the surface of the wafer can be effectively reduced by admixture of the hydrogen chloride gas during ramp-down, which is a final step in heat treatment.

In addition, we have also found that, in a MLD-SIMOX method, when a dose in a first oxygen ion implantation is high, silicon islands are formed in the BOX layer, lowering the dielectric withstanding voltage of the BOX layer. However, when the dose in the first oxygen ion implantation is set at 2×10¹⁷ atoms/cm² or less, that is, one-half or less of the dose in a low-dose SIMOX method, a continuous BOX layer can be formed and the dielectric breakdown strength properties of the BOX layer can be enhanced, in spite of the BOX layer having a thin thickness.

Accordingly, one aspect of a method for manufacturing a SIMOX wafer of the present invention is an improved method in which, as shown in FIGS. 1 and 2, oxygen ions are inplanted in a silicon wafer, then the silicon wafer is subjected to a prescribed heat treatment so as to form a BOX layer in the wafer.

This aspect of the invention is characterized in that the prescribed heat treatment includes: a step of ramping up a temperature of the silicon wafer in a low oxygen partial pressure gas atmosphere having an oxygen partial pressure ratio of less than 5%; either or both of a step of oxidizing the silicon wafer in a high oxygen partial pressure gas atmosphere having an oxygen partial pressure ratio of 5% or more and a step of annealing the silicon wafer in a low oxygen partial pressure gas atmosphere having an oxygen partial pressure ratio of less than 5%; and a step of ramping down the temperature of the silicon wafer in a low oxygen partial pressure gas atmosphere having an oxygen partial pressure ratio of less than 5%, and a hydrogen chloride gas is admixed with the low oxygen partial pressure gas having an oxygen partial pressure ratio of less than 5% in at least one step from among the ramp-up step, the anneal step and the ramp-down step.

In this method for manufacturing a SIMOX wafer, even though a large amount of hydrogen chloride gas is admixed with the low oxygen partial pressure gas in at least one step from among the ramp-up step, the anneal step and the ramp-down step in which the oxygen partial pressure ratio is set at less than 5%, the dielectric withstanding voltage of the BOX layer does not decrease. Hence, this hydrogen chloride gas bonds with contaminating metals such as iron and copper in the surface of the wafer, converting them to gases such as iron chloride and copper chloride and removing them from the wafer. As a result, metal contamination in the wafer surface can be reduced. In particular, by admixing a large amount of hydrogen chloride gas in the low oxygen partial pressure gas during the ramp-down step which is the final step in the prescribed heat treatment, the metal contamination in the surface of the heat-treated wafer can be reduced. Here, in the case in which the prescribed heat treatment includes an oxidation step, by setting the oxygen partial pressure ratio during oxidation treatment to 5% or more, the oxygen present in the high oxygen partial pressure gas can be used to form the BOX layer. However, when admixing a large amount of hydrogen chloride gas in this high oxygen partial pressure gas, an increase in a thickness of the BOX layer is suppressed and thus the dielectric withstanding voltage of the BOX layer is lowered. Therefore, either hydrogen chloride gas is not admixed or, if it is admixed, an admixed amount is held in check.

A second aspect of a method for manufacturing a SIMOX wafer of the present invention is a method in which, as shown in FIG. 1, the oxygen ion implantation includes: a first implantation step of implanting oxygen ions in a dose of 5×10¹⁶ to 2×10¹⁷ atoms/cm², while heated to 200° C. or more; and a second implantation step of implanting oxygen ions in a dose of 1×10¹⁴ to 5×10¹⁶ atoms/cm², while cooled to less than 200° C., which is carried out immediately after the first implantation step.

In this method for manufacturing a SIMOX wafer, because the oxygen ion dose in the first implantation step is set at 5×16 to 2×10¹⁷ atoms/cm², which is lower than the dose in prior-art of a low-dose SIMOX method, amount of silicon islands formed in the BOX layer can be reduced, metal contamination at the time of oxygen ion implantation can be decreased, and a time for implanting oxygen ions can be shortened. Moreover, because the oxygen ion dose in the second implantation step is set to a lower level than that in the first implantation step, the amount of the silicon islands formed in the BOX layer can be reduced.

In a third aspect of a method for manufacturing a SIMOX wafer of the present invention is a method in which, as shown in FIGS. 1 and 2, the oxygen ion implantation includes: a first implantation step of implanting oxygen ions in a dose of 5×10¹⁶ to 2×10¹⁷ atoms/cm², while heated to 200° C. or more; and a second implantation step of implanting oxygen ions in a dose of 1×10¹⁴ to 5×10¹⁶ atoms/cm², while cooled to less than 200° C., which is carried out immediately after the first implantation step, the prescribed heat treatment includes: a step of ramping up a temperature of the silicon wafer in a low oxygen partial pressure gas atmosphere having an oxygen partial pressure ratio of less than 5%; either or both of a step of oxidizing the silicon wafer in a high oxygen partial pressure gas atmosphere having an oxygen partial pressure ratio of 5% or more and a step of annealing the silicon wafer in a low oxygen partial pressure gas atmosphere having an oxygen partial pressure ratio of less than 5%; and a step of ramping down the temperature of the silicon wafer in a low oxygen partial pressure gas atmosphere having an oxygen partial pressure ratio of less than 5%, and a hydrogen chloride gas is mixed with the low oxygen partial pressure gas having an oxygen partial pressure ratio of less than 5% in at least one step from among the ramp-up step, the anneal step and the ramp-down step.

In this method for manufacturing a SIMOX wafer, two oxygen ion implantation steps enable to reduce the amount of silicon islands formed in the BOX layer, reduce metal contamination during oxygen ion implantation, and shorten the time for implanting oxygen ions. Moreover, even when a large amount of hydrogen chloride gas is admixed with the low oxygen partial pressure gas during a heat treatment carried out in the low oxygen partial pressure gas atmosphere, the dielectric withstanding voltage of the BOX layer does not decrease, and so metal contamination in the surface of the wafer can be reduced. As a result, there can be obtained a wafer which is clean and has excellent electrical properties.

In the first and third aspect of the methods for manufacturing a SIMOX wafer, a hydrogen chloride gas may be admixed in an amount of 0 to 0.02 vol % based on a total amount of gas during treating in the high oxygen partial pressure gas atmosphere having an oxygen partial pressure ratio of 5% or more, and a hydrogen chloride gas may be admixed in an amount of 0.02 to 10 vol % based on a total amount of gas during treating in the low oxygen partial pressure gas atmosphere having an oxygen partial pressure ratio of less than 5%.

Trans-Dichloroethylene may be used as a liquid source material for the hydrogen chloride gas.

### BRIEF DESCRIPTION OF THE DRAWINGS

FIG. 1 shows cross-sectional schematic views illustrating some of the steps in the method for manufacturing SIMOX wafer according to one embodiment of the invention.

FIG. 2 shows a timing chart of the heat treatment steps in the same process.

FIG. 3 is a diagram showing the effect of hydrogen chloride gas admixture in the heat treatment step on the dielectric withstanding voltage of the BOX layer in the wafer.

FIG. 4A is a diagram showing the effect of hydrogen chloride gas admixture in the heat treatment step on decontamination of metal (iron) from the wafer.

FIG. 4B is a diagram showing the effect of hydrogen chloride gas admixture in the heat treatment step on decontamination of metal (copper) from the wafer.

FIG. 5 is a diagram showing the effect of the oxygen ion dose in the first oxygen ion implantation step of the MLD-SIMOX process on the dielectric withstanding voltage of the BOX layer.

FIG. 6 is a graph showing the dielectric withstanding voltage of the BOX layer in wafers manufactured by the MLD-SIMOX process under the prescribed conditions.

### PREFERRED EMBODIMENTS

Embodiments of the invention are described below in conjunction with the attached figures.

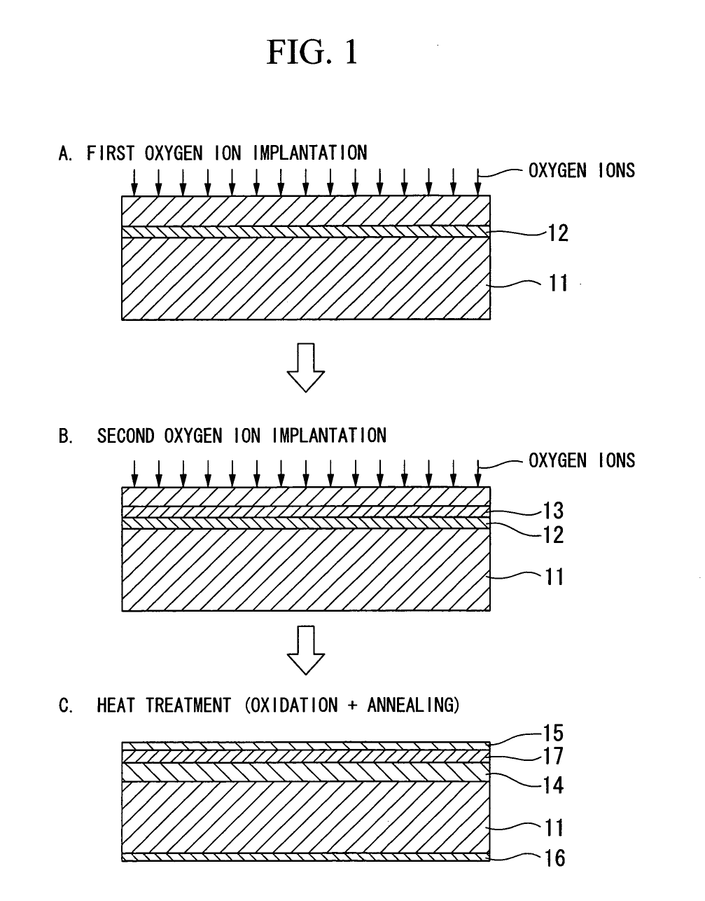

Referring to FIG. 1, a method for manufacturing SIMOX wafer includes a step of implanting oxygen ions in a silicon wafer 11 and a step of subjecting the resulting wafer 11 to a prescribed heat treatment. Although a method for manufacturing the wafer 11 by the MLD-SIMOX process is described in this embodiment, the description applies not only to the method for manufacturing SIMOX wafers by the MLD-SIMOX process, but also to methods for manufacturing SIMOX wafers by other SIMOX processes such as the ITOX-SIMOX process.

In the MLD-SIMOX process, oxygen ion implantation is carried out in two steps. A first oxygen ion implantation is carried out with the wafer 11 heated to 200° C. or more, and preferably 300 to 600° C., and at an oxygen ion dose of 5×10¹⁶ to 2×10¹⁷ atoms/cm², and preferably 1.25×10¹⁷ to 1.75×10¹⁷ atoms/cm² (first implantation step). A second oxygen ion implantation is carried out with the wafer 11 cooled to below 200° C., and preferably 25 to 100° C., and at an oxygen ion dose of 1×10¹⁴ to 5×10¹⁶ atoms/cm², and preferably 5×10¹⁴ to 1×10¹⁶ atoms/cm² (second implantation step).

The first oxygen ion implantation is carried out with the wafer 11 heated to 200° C. or more so as to maintain the surface of the wafer 11 as a single crystal and to form a high oxygen concentration layer 12 (A in FIG. 1) in the wafer 11. The second oxygen ion implantation is carried out with the wafer 11 cooled to below 200° C. so as to form an amorphous layer 13 (B in FIG. 1) in the wafer 11. The oxygen ion dose in the first implantation step is limited to a range of 5×10¹⁶ to 2×10¹⁷ atoms/cm² so as to reduce the formation of silicon islands in the heat-treated BOX layer 14. The oxygen ion dose in the second implantation step is lower than that in the first implantation step because a high oxygen ion dose in the second implantation step would result in a higher total amount of dose in the first and second implantation steps, increasing the formation of silicon islands in the BOX layer 14.

The above prescribed heat treatment includes a step of ramping up a temperature of the silicon wafer in a low oxygen partial pressure gas atmosphere having an oxygen partial pressure ratio of less than 5%, and preferably 0.5 to 4%; a step of oxidizing the silicon wafer in a high oxygen partial pressure gas atmosphere having an oxygen partial pressure ratio of 5% or more, and preferably 20 to 80%; a step of annealing the silicon wafer in a low oxygen partial pressure gas atmosphere having an oxygen partial pressure ratio of less than 5%, and preferably 0.5 to 4%; and a step of ramping down the temperature of the silicon wafer in a low oxygen partial pressure gas atmosphere having an oxygen partial pressure ratio of less than 5%, and preferably 0.5 to 4%. In this embodiment, oxidation treatment of the wafer 11 is immediately followed by annealing of the wafer 11. It should be noted that the hydrogen chloride gas is not admixed in a high oxygen partial pressure gas; the hydrogen chloride gas is admixed only in a low oxygen partial pressure gas. Here, “high oxygen partial pressure gas” refers to an inert gas containing oxygen in a partial pressure ratio of 5% or more, and “low oxygen partial pressure gas” refers to an inert gas containing oxygen in a partial pressure ratio of less than 5%. Examples of the inert gas include nitrogen and argon.

Aside from the direct use of HCl gas, trans-LC and trichloroethylene (TCA) can be used as a liquid source material for the hydrogen chloride gas. However, the use of TCA is restricted because it is an ozone layer-depleting substance. It is thus preferable to use trans-LC. Because trans-LC has a minimum process temperature of 750° C., trans-LC is admixed at a temperature of 750° C. or more during the prescribed heat treatment which includes a ramp-up step and a ramp-down step. It is preferable to use nitrogen or argon as the carrier gas for trans-LC. The above-described hydrogen chloride gas is admixed in an amount of 0 to 0.02 vol %, and preferably 0 to 0.01 vol %, based on the overall amount of gas during oxidation treatment, i.e., during high oxygen partial gas treatment at an oxygen partial pressure ratio of 5% or more; and hydrogen chloride gas is admixed in an amount of 0.02 to 10 vol %, and preferably 00.02 to 1 vol %, based on the overall amount of gas during annealing, i.e., during low oxygen partial pressure gas treatment at an oxygen partial pressure ratio of less than 5%.

The above-described hydrogen chloride gas is generated by bubbling a suitable gas such as nitrogen or argon through liquid trans-LC held in a quartz vessel, and is mixed in this state with the high oxygen partial pressure gas or low oxygen partial pressure gas. Here, a minimum amount of oxygen required is about twice a flow rate of the carrier gas.

The reason for limiting the oxygen partial pressure ratio to 5% or more and limiting the hydrogen chloride gas admixture flow rate to 0 to 0.02 vol % during oxidation treatment of the wafer 11 is to prevent a decrease in the dielectric withstanding voltage of the BOX layer. The reason for limiting the hydrogen chloride gas admixture flow rate to 0.02 to 10 vol % during treatment at an oxygen partial pressure ratio of less than 5% is to reduce metal contamination in the surface of the wafer 11 without causing a decline in the dielectric withstanding voltage of the BOX layer to decrease.

The above-described oxidation treatment and annealing are carried out by heating the wafer 11 to 1300° C. or more, and preferably 1320 to 1350° C., and holding the temperature at this level for 4 to 16 hours, and preferably 8 to 12 hours. A BOX layer 14 is formed in this way in the wafer 11 (C in FIG. 1). The thicknesses of the surface oxide layers 15 and 16 can be adjusted by varying the oxygen partial pressure ratio and heat treatment time within the above ranges, thus enabling the thickness of the SOI layer 17 to be controlled.

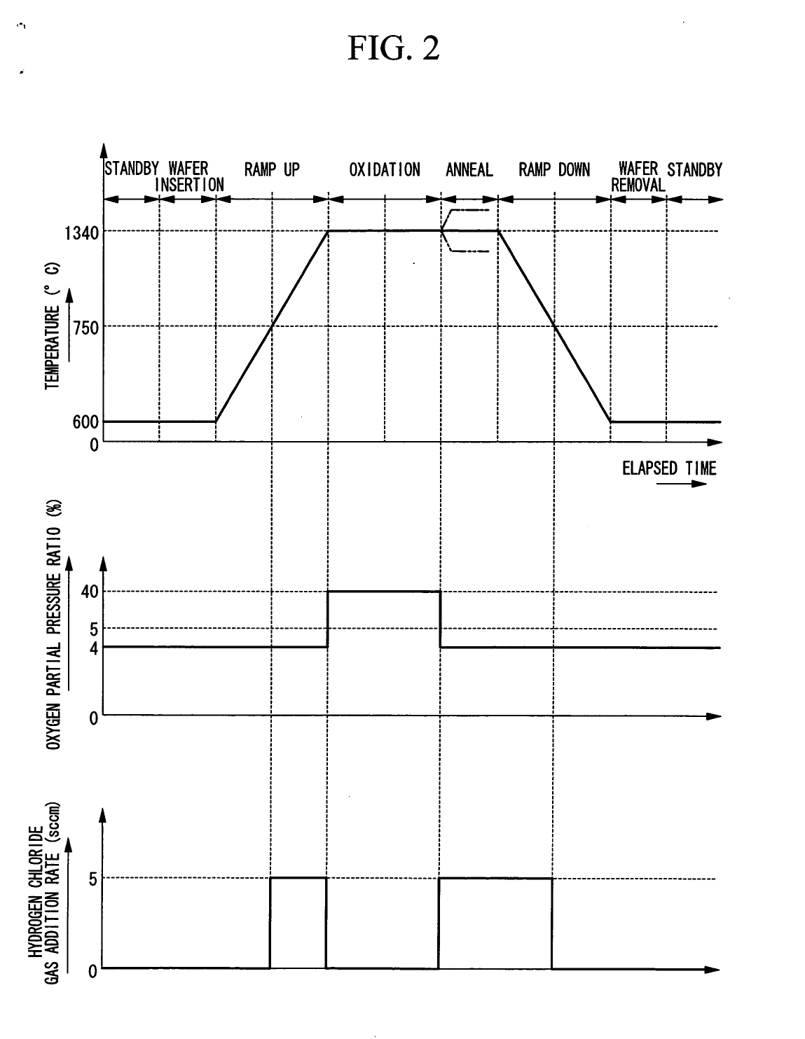

The wafer may be subjected to an oxidation treatment after it has been annealed. In this case, the atmosphere in the ramp-down step following oxidation treatment is preferably a low oxygen partial pressure gas atmosphere having an oxygen partial pressure ratio of less than 5% in which the hydrogen chloride gas is admixed. The heating temperature during oxidation treatment and the heating temperature during annealing may be the same or different. In the case in which they are different (indicated by the dash-dot and dash-dot-dot lines in FIG. 2), the atmosphere in a ramp-up step and a ramp-down step between the oxidation treatment and the annealing is preferably a low oxygen partial pressure gas having an oxygen partial pressure of less than 5% in which the hydrogen chloride gas is admixed.

Alternatively, the prescribed heat treatment described above may include a ramp-up step, an oxidation treatment step and a ramp-down step without including an annealing step, or may include a ramp-up step, an annealing step and a ramp-down step without including an oxidation treatment step.

In SIMOX wafers manufactured by the above-described MLD-SIMOX process, by having the oxygen ion dose in the first implantation step be from 5×10¹⁶ to 2×10¹⁷ atoms/cm², which is lower than the dose in prior-art low-dose SIMOX processes (4×10¹⁷ atoms/cm²), the formation of silicon islands in the BOX layer 14 can be reduced, enabling the dielectric withstanding voltage of the BOX layer 14 to be improved. In addition, metal contamination during oxygen ion implantation can be reduced and the time for implanting oxygen ions can be shortened, thus making it possible to reduce the production costs of the wafers 11. Also, by having the oxygen ion dose in the second implantation step be lower than the oxygen ion dose in the first implantation step, the formation of silicon islands in the BOX layer 14 can be reduced, enabling the dielectric withstanding voltage of the BOX layer 14 to be improved. In addition, because hydrogen chloride gas is not admixed in the high oxygen partial pressure gas used in oxidation treatment, a decline in the dielectric withstanding voltage of the BOX layer 14 induced by a hydrogen chloride gas can be prevented. Also, because hydrogen chloride gas is admixed in the low oxygen partial pressure gas at the time of ramp-up, annealing and ramp-down during heat treatment, contaminating metals such as iron and copper in the surface of the wafer can be removed in the form of gases such as iron chloride and copper chloride without causing a decline in the dielectric withstanding voltage of the BOX layer 14. As a result, metal contamination in the surface of the wafer 11 can be reduced. Accordingly, because metal contamination in the surface of the wafer can be reduced and the dielectric withstanding voltage of the BOX layer in the SIMOX wafer can be increased, there can be obtained wafers which are clean and have excellent electrical properties 11.

### EXAMPLES

Examples of the invention and comparative examples are given below by way of illustration.

### Example 1

A silicon wafer 11 was manufactured by the MLD-SIMOX process, as shown in FIG. 1. First, oxygen ion implantation of the wafer 11 was carried out in two steps. In the first oxygen ion implantation step, the wafer 11 was heated in a vacuum to 400° C., and implantation was carried out at an oxygen ion dose of 3×10¹⁷ atoms/cm². In the second oxygen ion implantation step, which immediately followed the first oxygen ion implantation step, the temperature of the wafer 11 was lowered to room temperature and implantation was carried out at an oxygen ion dose of 2×10¹⁵ atoms/cm². In this way, the surface of the wafer 11 remained a single crystal and a high oxygen concentration layer 12 and an amorphous layer 13 were formed in the wafer 11.

Next, the wafer 11 was placed in a heat treatment furnace, the temperature was raised to 1340° C. at a ramp rate of 1° C./min in a ramp-up step, held at 1340° C. for 10 hours in an oxidation treatment step, held at 1340° C. for 5 hours in an annealing step, then lowered to 600° C. at a ramp rate of 1° C./min in a ramp-down step. In the annealing step on the wafer 11, treatment was carried out by feeding argon gas containing oxygen in a partial pressure ratio of 4% to the heat treatment furnace at a flow rate of 25 slm, feeding trans-LC along with a carrier gas at a flow rate of 5 sccm, and mixing the two gases. In a ramp-up step and a ramp-down step on the wafer 11, treatment was carried out by feeding only argon gas containing oxygen in a partial pressure ratio of 4% to the heat treatment furnace at a flow rate of 25 slm. Moreover, in the oxidation treatment step on the wafer 11, treatment was carried out by feeding only argon gas containing oxygen in a partial pressure ratio of 40% to the heat treatment furnace at a flow rate of 25 slm. The wafer 11 manufactured in this way was “Example 1”.

### Example 2

In the wafer ramp-down step, treatment was carried out by feeding argon gas containing oxygen in a partial pressure ratio of 4% to the heat treatment furnace at a flow rate of 25 slm, feeding trans-LC along with a carrier gas at a flow rate of 5 sccm, and mixing the two gases. In the wafer ramp-up step and anneal step, treatment was carried out by feeding only argon gas containing oxygen in a partial pressure ratio of 4% to the heat treatment furnace at a flow rate of 25 slm. In the wafer oxidation treatment step, treatment was carried out by feeding only argon gas containing oxygen in a partial pressure ratio of 40% to the heat treatment furnace at a flow rate of 25 slm. Aside from the above, a wafer was manufactured in the same way as in Example 1. This wafer was “Example 2”.

### Example 3

In the wafer ramp-up step, treatment was carried out by feeding argon gas containing oxygen in a partial pressure ratio of 4% to the heat treatment furnace at a flow rate of 25 slm, feeding trans-LC along with a carrier gas at a flow rate of 5 sccm, and mixing the two gases. In the wafer anneal step and ramp-down step, treatment was carried out by feeding only argon gas containing oxygen in a partial pressure ratio of 4% to the heat treatment furnace at a flow rate of 25 slm. In the wafer oxidation treatment step, treatment was carried out by feeding only argon gas containing oxygen in a partial pressure ratio of 40% to the heat treatment furnace at a flow rate of 25 slm. Aside from the above, a wafer was manufactured in the same way as in Example 1. This wafer was “Example 3”.

### Comparative Example 1

In the wafer ramp-up step, anneal step and ramp-down step, treatment was carried out by feeding only argon gas containing oxygen in a partial pressure ratio of 4% to the heat treatment furnace at a flow rate of 25 slm. In the wafer oxidation treatment step, treatment was carried out by feeding only argon gas containing oxygen in a partial pressure ratio of 40% to the heat treatment furnace at a flow rate of 25 slm. Aside from this, a wafer was manufactured in the same way as in Example 1. This wafer was “Comparative Example 1”.

### Comparative Example 2

In the wafer ramp-up step, anneal step and ramp-down step, treatment was carried out by feeding argon gas containing oxygen in a partial pressure ratio of 4% to the heat treatment furnace at a flow rate of 25 slm, feeding trans-LC along with a carrier gas at a flow rate of 5 sccm, and mixing the two gases. In the wafer oxidation step, treatment was carried out by feeding argon gas containing oxygen in a partial pressure ratio of 40% to the heat treatment furnace at a flow rate of 25 slm, feeding trans-LC along with a carrier gas at a flow rate of 5 sccm, and mixing the two gases. Aside from this, a wafer was manufactured in the same way as in Example 1. This wafer was “Comparative Example 2”.

### Comparative Example 3

In the wafer oxidation treatment step, treatment was carried out by feeding argon gas containing oxygen in a partial pressure ratio of 40% to the heat treatment furnace at a flow rate of 25 slm, feeding trans-LC along with a carrier gas at a flow rate of 5 sccm, and mixing the two gases. In the wafer ramp-up step, anneal step and ramp-down step, treatment was carried out by feeding only argon gas containing oxygen in a partial pressure ratio of 4% to the heat treatment furnace at a flow rate of 25 slm. Aside from this, a wafer was manufactured in the same way as in Example 1. This wafer was “Comparative Example 3”.

(Test 1 and Evaluation)

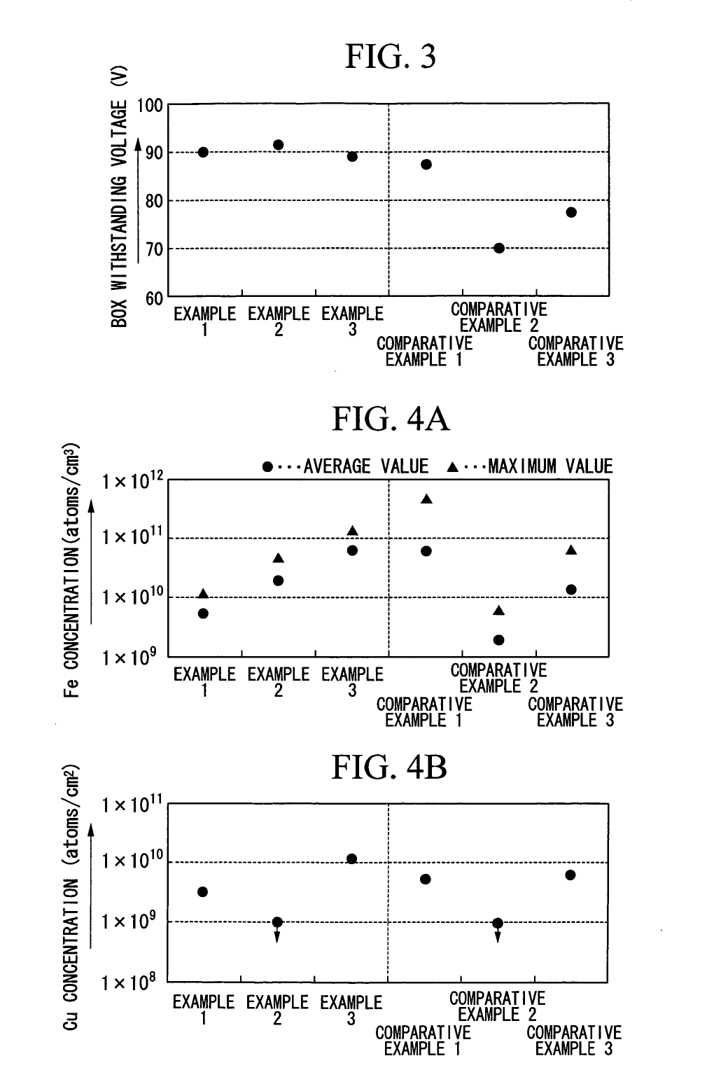

The dielectric withstanding voltages of the BOX layers in the MLD-SIMOX wafers of Examples 1 to 3 and Comparative Examples 1 to 3 were measured. Those results are shown in FIG. 3.

As is apparent from FIG. 3, in Comparative Example 1 (an example in which no trans-LC whatsoever was admixed during heat treatment), the dielectric withstanding voltage of the BOX layer was 88 V, which is relatively high. However, the dielectric withstanding voltage decreased to 70 V in Comparative Example 2 (an example in which trans-LC was admixed at a carrier gas flow rate of 5 sccm in all the following steps: ramp-up step, oxidation treatment step, anneal step and ramp-down step), and to 77 V in Comparative Example 3 (an example in which trans-LC was admixed at a carrier gas flow rate of 5 sccm in the oxidation treatment step). In contrast, in Example 1 of the present invention (an example in which trans-LC was admixed at a carrier gas flow rate of 5 sccm in the anneal step), the dielectric withstanding voltage of the BOX layer was substantially undiminished at 90 V. Similarly, in Example 2 (an example in which trans-LC was admixed at a carrier gas flow rate of 5 sccm in the ramp-down step), the dielectric withstanding voltage of the BOX layer was substantially undiminished at 92 V, and in Example 3 (an example in which trans-LC was admixed at a carrier gas flow rate of 5 sccm in the ramp-up step), the dielectric withstanding voltage of the BOX layer was substantially undiminished at 89 V.

(Test 2 and Evaluation)

The iron concentration in the wafers obtained in Examples 1 to 3 and Comparative Examples 1 to 3 was measured by surface photovoltage spectroscopy (SPC), and the copper concentration in the surface of the wafer was measured by atomic absorption spectroscopy (AAS). The results are shown in FIGS. 4A and 4B.

As is apparent from FIG. 4A, in Comparative Example 2 (an example in which trans-LC was admixed at a carrier gas flow rate of 5 sccm in all the following steps: ramp-up step, oxidation treatment step, anneal step and ramp-down step), the average iron concentration in the wafer decreased to about 2×10⁹ atoms/cm³ and the maximum concentration decreased to about 7×10⁹ atoms/cm³. Yet, a relatively high levels of iron were detected in Comparative Example 1 (an example in which no trans-LC whatsoever was admixed during heat treatment), where the average iron concentration in the wafer was about 9×10¹⁰ atoms/cm³ and the maximum concentration was about 6×10¹¹ atoms/cm³, and in Comparative Example 3 (an example in which trans-LC was admixed at a carrier gas flow rate of 5 sccm in the oxidation treatment step), where the average iron concentration in the wafer was about 2×10¹⁰ atoms/cm³ and the maximum concentration was about 8×10¹⁰ atoms/cm³. In contrast, it is apparent that in Example 1 of the present invention (an example in which trans-LC was admixed at a carrier gas flow rate of 5 sccm in the anneal step), the average iron concentration in the wafer decreased to about 7×10⁹ atoms/cm³ and the maximum concentration decreased to about 1.5×10¹⁰ atoms/cm³, and that in Example 2 (an example in which trans-LC was admixed at a carrier gas flow rate of 5 sccm in the ramp-down step), the average iron concentration in the wafer decreased to about 3×10¹⁰ atoms/cm³ and the maximum concentration decreased to about 7×10¹⁰ atoms/cm³. In Example 3 (an example in which trans-LC was admixed at a carrier gas flow rate of 5 sccm in the ramp-up step), the average iron concentration in the wafer was about 8×10¹⁰ atoms/cm³ and the maximum concentration was about 2×10¹¹ atoms/cm³. A relatively large amount of iron was detected in this latter case because iron entered the wafer as a contaminating metal subsequent to the oxidation treatment following ramp-up.

As is apparent from FIG. 4B, in Comparative Example 2 (an example in which trans-LC was admixed at a carrier gas flow rate of 5 sccm in all the following steps: ramp-up step, oxidation treatment step, anneal step and ramp-down step), the average copper concentration in the surface of the wafer was relatively low at about 1×10⁹ atoms/cm² or less. However, relatively high levels of copper were detected in Comparative Example 1 (an example in which no trans-LC whatsoever was admixed during heat treatment), where the average copper concentration in the surface of the wafer was about 7×10⁹ atoms/cm², and in Comparative Example 3 (an example in which trans-LC was admixed at a carrier gas flow rate of 5 sccm in the oxidation treatment step), where the average copper concentration in the surface of the wafer was about 8×10⁹ atoms/cm². In contrast, it is apparent that in Example 1 of the invention (an example in which trans-LC was admixed at a carrier gas flow rate of 5 sccm in the anneal step), the average copper concentration in the surface of the wafer decreased to about 7×10⁹ atoms/cm², and in Example 2 (an example in which trans-LC was admixed at a carrier gas flow rate of 5 sccm in the ramp-down step), the average copper concentration in the surface of the wafer decreased to about 1×10⁹ atoms/cm² or less. In Example 3 (an example in which trans-LC was admixed at a carrier gas flow rate of 5 sccm in the ramp-up step), the average copper concentration in the surface of the wafer was about 1.5×10¹⁰ atoms/cm². A relatively large amount of cupper was detected in this latter case because copper entered the wafer as a contaminating metal subsequent to the oxidation treatment following ramp-up.

### Example 4

Aside from setting the oxygen ion dose in the first implantation step to 1.25×10¹⁷ atoms/cm² and setting the oxygen ion dose in the second implantation step to 2×10¹⁵ atoms/cm², a wafer was manufactured in the same way as in Comparative Example 2. This wafer was “Example 4”.

### Example 5

Aside from setting the oxygen ion dose in the first implantation step to 1.5×10¹⁷ atoms/cm² and setting the oxygen ion dose in the second implantation step to 2×10¹⁵ atoms/cm², a wafer was manufactured in the same way as in Comparative Example 2. This wafer was “Example 5”.

### Example 6

Aside from setting the oxygen ion dose in the first implantation step to 1.75×10¹⁷ atoms/cm² and setting the oxygen ion dose in the second implantation step to 2×10¹⁵ atoms/cm², a wafer was manufactured in the same way as in Comparative Example 2. This wafer was “Example 6”.

### Example 7

Aside from setting the oxygen ion dose in the first implantation step to 2.0×10¹⁷ atoms/cm² and setting the oxygen ion dose in the second implantation step to 2×10¹⁵ atoms/cm², a wafer was manufactured in the same way as in Comparative Example 2. This wafer was “Example 7”.

### Comparative Example 4

Aside from setting the oxygen ion dose in the first implantation step to 2.25×10¹⁷ atoms/cm² and setting the oxygen ion dose in the second implantation step to 2×10¹⁵ atoms/cm², a wafer was manufactured in the same way as in Comparative Example 2. This wafer was “Comparative Example 4”.

### Comparative Example 5

Aside from setting the oxygen ion dose in the first implantation step to 2.5×10¹⁷ atoms/cm² and setting the oxygen ion dose in the second implantation step to 2×10¹⁵ atoms/cm², a wafer was manufactured in the same way as in Comparative Example 2. This wafer was “Comparative Example 5”.

(Test 3 and Evaluation)

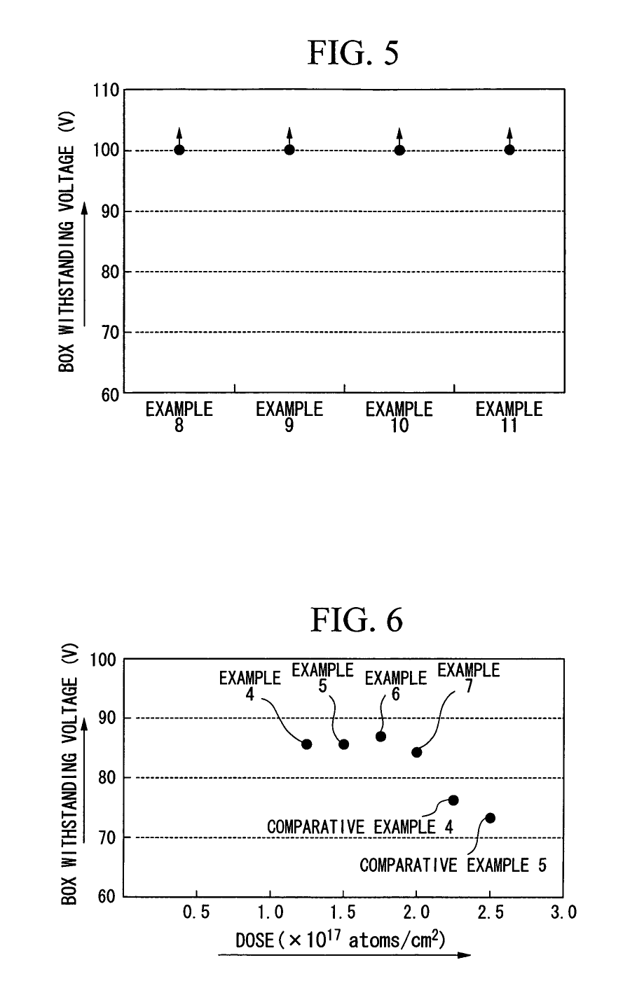

The dielectric withstanding voltages of the BOX layers in the MLD-SIMOX wafers obtained in Examples 4 to 7 and in Comparative Examples 4 and 5 were measured. Measurement was carried out in the same way as described in Test 1 above. The results are shown in FIG. 5.

As is apparent from FIG. 5, the dielectric withstanding voltage of the BOX layer rose as the oxygen ion dose decreased. In particular, it was found that a good dielectric withstanding voltage can be obtained in the Box layer with a decrease in the dose to 2×10¹⁷ atoms/cm² or below.

### Examples 8 to 11

Aside from carrying out oxygen ion implantation of the wafer at an oxygen ion dose in the first implantation step of 1.75×10¹⁷ atoms/cm² and an oxygen ion dose in the second implantation step of 2×10¹⁵ atoms/cm², four wafers were manufactured in the same way as in Example 2. These wafers were “Examples 8 to 11”.

(Test 4 and Evaluation)

The dielectric withstanding voltages of the BOX layers in the MLD-SIMOX wafers obtained in Examples 8 to 11 were measured in the same way as described in Test 1 above. The results are shown in FIG. 6.

As is apparent from FIG. 6, in the wafers obtained in Examples 8 to 11 which were manufactured under a combination of ion implanting conditions capable of reducing silicon islands and heat treatment conditions capable of removing metal contaminants in the surface of the SIMOX wafers without lowering the dielectric withstanding voltage of the BOX layer, it was possible to obtain excellent dielectric withstanding voltages in the BOX layer. In each of the wafers obtained in Examples 8 to 11, the BOX layer formed had a thickness of 0.14 μm and a dielectric withstanding voltage of 100 V or more.

As shown above, in the instant process, a hydrogen chloride gas is admixed with low oxygen partial pressure gas having an oxygen partial pressure ratio of less than 5% in at least one step from among the silicon wafer ramp-up step, the anneal step and the ramp-down step, thus enabling contaminating metals such as iron and copper at the surface of the wafer or in the wafer to be removed in the form of gases such as iron chloride and copper chloride without lowering the dielectric withstanding voltage of the BOX layer.

Also, by implanting oxygen ions at a dose of 5×10¹⁶ to 2×10¹⁷ atoms/cm² with the silicon wafer heated to 200° C. or more in a first implantation step and implanting oxygen ions at a dose of 1×10¹⁴ to 5×10¹⁶ atoms/cm² with the silicon wafer cooled to below 200° C. in a second implantation step, the formation of silicon islands in the BOX layer can be reduced, making it possible to prevent a decline in the dielectric withstanding voltage of the BOX layer. In addition, metal contamination during ion implantation can be reduced and the ion implanting time can be shortened, enabling the production costs for the wafer to be reduced.

Also, by admixing a hydrogen chloride gas in a low oxygen partial pressure gas having an oxygen partial pressure ratio of less than 5% when heat treatment is carried out in a low oxygen partial pressure gas atmosphere following the above second oxygen ion implantation step, the formation of silicon islands in the BOX layer can be reduced, metal contamination during oxygen ion implantation can be reduced, and the time for implanting oxygen ions can be shortened, in addition to which metal contamination in the surface of the wafer can be reduced without lowering the dielectric withstanding voltage of the BOX layer 14. As a result, there can be obtained wafers which are clean and have excellent electrical properties.

Some preferred embodiments of the invention have been described above, although these embodiments are to be considered in all respects as illustrative and not limitative. Those skilled in the art will appreciate that various additions, omissions, substitutions and other modifications are possible without departing from the spirit and scope of the invention as disclosed in the accompanying claims.

1. A method for manufacturing a SIMOX wafer, comprising implanting oxygen ions into a silicon wafer and then subjecting the silicon wafer to a prescribed heat treatment so as to form a buried oxide layer in the silicon wafer,
wherein the prescribed heat treatment comprises:
a step of ramping up a temperature of the silicon wafer in a low oxygen partial pressure gas atmosphere having an oxygen partial pressure ratio of less than 5%;
either or both of a step of oxidizing the silicon wafer in a high oxygen partial pressure gas atmosphere having an oxygen partial pressure ratio of 5% or more and a step of annealing the silicon wafer in a low oxygen partial pressure gas atmosphere having an oxygen partial pressure ratio of less than 5%; and
a step of ramping down the temperature of the silicon wafer in a low oxygen partial pressure gas atmosphere having an oxygen partial pressure ratio of less than 5%, and
a hydrogen chloride gas is mixed with the low oxygen partial pressure gas having an oxygen partial pressure ratio of less than 5% in at least one step from among the ramp-up step, the anneal step and the ramp-down step.

2. A method for manufacturing a SIMOX wafer, comprising implanting oxygen ions into a silicon wafer and then subjecting the silicon wafer to a prescribed heat treatment so as to form a buried oxide layer in the silicon wafer,
wherein the oxygen ion implantation comprises:
a first implantation step of implanting oxygen ions in a dose of 5×10¹⁶ to 2×10¹⁷ atoms/cm², while heated to 200° C. or more; and
a second implantation step of implanting oxygen ions in a dose of 1×10¹⁴ to 5×10¹⁶ atoms/cm², while cooled to less than 200° C., which is carried out immediately after the first implantation step.

3. A method for manufacturing a SIMOX wafer, comprising implanting oxygen ions into a silicon wafer and then subjecting the silicon wafer to a prescribed heat treatment so as to form a buried oxide layer in the silicon wafer,
wherein the oxygen ion implantation comprises:
a first implantation step of implanting oxygen ions in a dose of 5×10¹⁶ to 2×10¹⁷ atoms/cm², while heated to 200° C. or more; and
a second implantation step of implanting oxygen ions in a dose of 1×10¹⁴ to 5×10¹⁶ atoms/cm², while cooled to less than 200° C., which is carried out immediately after the first implantation step,
the prescribed heat treatment comprises:
a step of ramping up a temperature of the silicon wafer in a low oxygen partial pressure gas atmosphere having an oxygen partial pressure ratio of less than 5%;
either or both of a step of oxidizing the silicon wafer in a high oxygen partial pressure gas atmosphere having an oxygen partial pressure ratio of 5% or more and a step of annealing the silicon wafer in a low oxygen partial pressure gas atmosphere having an oxygen partial pressure ratio of less than 5%; and
a step of ramping down the temperature of the silicon wafer in a low oxygen partial pressure gas atmosphere having an oxygen partial pressure ratio of less than 5%, and
a hydrogen chloride gas is mixed with the low oxygen partial pressure gas having an oxygen partial pressure ratio of less than 5% in at least one step from among the ramp-up step, the anneal step and the ramp-down step.

4. A method for manufacturing a SIMOX wafer according to claim 3,
wherein a hydrogen chloride gas is admixed in an amount of 0 to 0.02 vol % based on a total amount of gas during treating in the high oxygen partial pressure gas atmosphere having an oxygen partial pressure ratio of 5% or more, and
a hydrogen chloride gas is admixed in an amount of 0.02 to 10 vol % based on a total amount of gas during treating in the low oxygen partial pressure gas atmosphere having an oxygen partial pressure ratio of less than 5%.

5. A method for manufacturing a SIMOX wafer according to claim 4, wherein trans-dichloroethylene is used as a liquid source material for the hydrogen chloride gas.

6. A method for manufacturing a SIMOX wafer according to claim 3, wherein trans-dichloroethylene is used as a liquid source material for the hydrogen chloride gas.

7. A method for manufacturing a SIMOX wafer according to claim 1,
wherein a hydrogen chloride gas is admixed in an amount of 0 to 0.02 vol % based on a total amount of gas during treating in the high oxygen partial pressure gas atmosphere having an oxygen partial pressure ratio of 5% or more, and
a hydrogen chloride gas is admixed in an amount of 0.02 to 10 vol % based on a total amount of gas during treating in the low oxygen partial pressure gas atmosphere having an oxygen partial pressure ratio of less than 5%.

8. A method for manufacturing a SIMOX wafer according to claim 7, wherein trans-dichloroethylene is used as a liquid source material for the hydrogen chloride gas.

9. A method for manufacturing a SIMOX wafer according to claim 1, wherein trans-dichloroethylene is used as a liquid source material for the hydrogen chloride gas.
